(19) United States
(12) Patent Application Publication
(10) Pub. No.: US 2005/0110057 A1
(43) Pub. Date: May 26, 2005

(54) Endurance improvement by sidewall nitridation of poly floating gate for nonvolatile memory devices using substrate or drain-side erase scheme

(75) Inventors: Shih Wei Wang, Hsin Chu (TW); Chia-Dar Hsieh, Tainan (TW)

Correspondence Address: GEORGE O. SAILE, 28 DAVIS AVENUE, POUGHKEEPSIE, NY, 12603, US

(73) Assignee: Taiwan Semiconductor Manufacturing Co.

(21) Appl. No.: 10/718,877

(22) Filed: Nov. 21, 2003

(51) Int. Cl. H01L 29/76

(52) U.S. Cl. 257/288; 438/585

(57) ABSTRACT

A gate structure is disclosed with improved endurance characteristics. Source and drain regions are contained within a semiconductor region of a substrate. At least a gate stack, which is disposed over the semiconductor region, is situated between the source and drain regions. The gate stack contains a gate insulator layer formed over the semiconductor region, a conductive gate layer disposed over the gate insulator layer, a top gate stack layer disposed over the conductive gate layer. A sidewall insulator layer is disposed over sidewalls of the gate stack. Nitrogen atoms are incorporated along the conductive gate layer sidewall-sidewall insulator layer interface and along the conductive gate layer-gate insulator layer interface in the vicinity of the conductive gate layer edge.

### BACKGROUND OF THE INVENTION

(1) Field of the Invention

The present invention relates generally to semiconductor integrated circuit technology and more particularly to nonvolatile memory devices such as flash EEPROMs (Electrically Erasable Programmable Read Only Memory).

(2) Description of Prior Art

The role of floating gates in nonvolatile memory devices is well known. In programming operations electrons are injected into floating gates where they are stored. Erasing operations remove the stored charge from floating gates. Thus, there are two states, charged and uncharged, that floating gates could be in. Read operations are used to determine in which of the two states particular floating gates are in. This is accomplished utilizing the affect of a negatively charged floating gate of causing an increase in the threshold voltage, which is the applied voltage required to obtain a conducting channel. Since the threshold voltage is larger for charged floating gates than for uncharged floating gates, applying a voltage intermediate between the threshold voltages will result in a conducting channel only for the uncharged floating gates. Therefore, the state of a floating gate is determined by the conduction state of the channel upon application of such an intermediate voltage.

As is well known, the vicinity of polysilicon surfaces and interfaces are regions where large concentrations of electron trapping states can be found. Since floating gates are predominately polysilicon, the vicinities of floating gate-gate dielectric interfaces and floating gate-dielectric spacer interfaces are regions where large concentrations of electron trapping states are found. When electrons are trapped in these trapping states the operation of nonvolatile memory devices can be severely effected. Such trapped electrons cause increases in the threshold voltage, which accumulate as the memory device is cycled through programming and erase cycles. Changes in time of the operating characteristics of a memory device are referred to as its endurance characteristics. Thus the accumulation of interfacial trapped electrons impacts the endurance characteristics of a nonvolatile memory device by their effect on the threshold voltage. Eventually the trapped electronic charge could increase sufficiently so that the threshold voltage is as large or larger than the control gate voltage used in the read operation, in which case an error ensues. Another severe impact of interfacial trapped electrons on the endurance characteristics of nonvolatile memory devices is that they cause a decrease in the efficiency of the erase operation when drain side or channel erase schemes are used.

These affects are shown in FIGS. 1 and 2 for a typical conventional nonvolatile flash memory device. Shown in FIGS. 1 and 2 is a portion of a flash memory cell, which could be a portion of a stacked-gate flash or of a split gate flash. Region 2 is a semiconductor region, which could be a silicon region such as a silicon substrate, in which there is formed a drain region, 4. A gate insulator layer, 6, which could be a tunnel oxide layer, is formed over the semiconductor region. A floating gate, 8, that is often polysilicon, is disposed over the gate insulator layer and is separated from a control gate, 10, that is also often polysilicon, by an intergate insulator layer, 12, that can be an ONO layer. Top dielectric layer, 14 insulates the control gate and sidewall insulator layer, 16, insulates the control gate and the floating gate.

In a programming operation the control gate is biased positive with respect to the semiconductor region, 2, so that electrons are injected into the floating gate, 8, through the gate insulator layer. For a fresh flash memory cell the erase operation is as shown in FIG. 1. The control gate is now biased negative so that free electrons, 18, are injected into the drain region, 4, and semiconductor region, 2, by tunneling through the gate insulator layer, 6, and the sidewall insulator spacer, 16. However the tunneling at the floating gate edge, denoted by the arrows 20, dominates the tunneling current with relatively little contribution from the tunneling away from the edges, 22. This domination of the current by the tunneling at the floating gate edge will prevail for either drain side or channel erase schemes.

The effect of cycling is shown in FIG. 2. As for the fresh memory cell of FIG. 1, the control gate is biased negative so that free electrons, 18, are injected into the drain region, 4, and semiconductor region, 2, by tunneling through the gate insulator layer, 6, and the sidewall insulator spacer, 16. Cycling here refers to repetition of the programming operation-erasing operation pair. Electron trapping occurs during the erase operation at the floating gate-gate insulator layer and floating gate-sidewall insulator spacer interfaces. More electrons are trapped where there are more free electrons so that a trapped electron distribution, 24, results with many more electrons trapped near the floating gate edge, as shown in FIG. 2. Since trapped electrons have a greatly diminished tunneling probability and there are far fewer free electrons near the floating gate edge, cycling results in significant decrease in the tunneling at the floating gate edge and the erase current, now predominately due to tunneling away from the edge, is significantly diminished. Thus the efficiency of the erase operation is degraded.

Trapped negative charge at floating gate interfaces causes an increase in the threshold voltage Vₜ. Cycling therefore gives rise to increasing Vₜ corresponding to increasing trapped electrons at the floating gate-gate insulator and floating gate-sidewall insulator spacer interfaces. This effect is shown quantitatively in FIGS. 4, 5 and 6 for a split gate memory cell test structure as shown in FIG. 3. The gate region is composed of two stacks over a p-type silicon substrate, 26. One stack, on the drain, 36, side is composed of a tunnel oxide layer, 28, which is about 90 to 100 Angstroms thick; a polysilicon floating gate, 30, which is about 800 to 1000 Angstroms thick and whose width and length are each about 0.15 micrometers; an inter poly ONO layer, 32, with a thickness of about 60 Angstroms for each of the three layers and a polysilicon control gate, 34, which is about 1000 to 1500 Angstroms thick. The source, 38, side stack is composed of the tunnel oxide layer, 28, over the substrate, 26, and a polysilicon transfer gate, 40, which is about 800 to 1000 Angstroms thick. In the cycling, the programming was accomplished by source side hot electron injection from the channel into the floating gate and the erase operation involved Fowler-Nordheim tunneling into the whole channel with the control gate biased negative and all other terminals grounded. In the read operation the threshold voltage, VT, is determined as the control gate voltage required to achieve 1 microampere of drain current.

In FIG. 4, VT measured after programming, for a traditional memory cell, is presented as curve 42 as a function of the number of cycles, N and VT measured after erasing, for a traditional memory cell, is presented as curve 44 as a function of N. Accumulation of negative trapped charge is apparent by the monotonic increase of VT with N. The increases in VT that are obtained for the traditional memory cell are shown directly in FIGS. 5 and 6, which present the VT shifts, VT minus the initial VT, after programming as curve 46 and after erasing as curve 48. Relatively large VT shifts are seen to occur even for moderate N. The VT shifts are large enough that errors are to be expected to occur in the operation of the device even after relatively short operating times.

Although the effects of electron trapping have been discussed above with reference to flash memory cell structures the phenomena occurs in wider class of gate structures. The present invention, to alleviate these affects, is applicable to the wider class of gate structures.

Ho et al. U.S. Pat. No. 6,417,046 discloses a modified nitride spacer with significantly improved charge retention in floating gate memory cells. Karooka et al. U.S. Pat. No. 6,184,088 teaches a method to fabricate a split-gate type transistor with a nitrated floating gate. U.S. Pat. No. 6,268,624 to Sobek et al. shows a method for inhibiting tunnel oxide thickening by forming protective barrier films. U.S. Pat. 5,966,606 to Ono discloses a method for forming a sidewall film of a gate electrode by forming a thin silicon nitride film through nitridation of the gate electrode and a relatively thick silicon nitride film. Aminzadeh et al., U.S. Pat. 5,827,769, shows a method of fabricating a transistor by nitridizing the sidewall oxide of the gate electrode.

### SUMMARY OF THE INVENTION

It is a primary objective of the invention to provide a gate structure in which the vicinities of floating gate-gate dielectric interfaces near a floating gate edge and floating gate-dielectric spacer interfaces contain reduced concentrations of electron trapping states. It is a further primary objective of the invention to provide a gate structure with improved endurance characteristics. It is yet a further primary objective of the invention to provide a gate structure with reduced erase operation efficiency degradation. Another primary objective of the invention is to provide a method of forming a gate structure in which the vicinities of floating gate-gate dielectric interfaces near a floating gate edge and floating gate-dielectric spacer interfaces contain reduced concentrations of electron trapping states. Yet a further primary objective of the invention is to provide a method of forming a gate structure with improved endurance characteristics. Yet another primary objective of the invention is to provide a method of forming a gate structure with reduced erase operation efficiency degradation.

These objectives are met in the invention by the reduction of the electron trap concentration in vicinities of floating gate-gate dielectric interfaces near a floating gate edge and floating gate-dielectric spacer interfaces that is a consequence of a nitridation treatment, introduced in the invention, on the exposed floating gate sidewall before spacer formation. This reduction results by the incorporation of nitrogen atoms in the vicinity of the exposed floating gate sidewall surface and in the vicinity of floating gate-gate dielectric interfaces near a floating gate sidewall surface. Incorporated nitrogen atoms serve to fulfill bonds in these vicinities that would otherwise act as electron traps. Comparison of the endurance characteristics of split gate flesh memory cells with and without the extra nitridation treatment clearly demonstrates the significant improvement in the endurance characteristics resulting from the nitridation treatment.

### BRIEF DESCRIPTION OF THE DRAWINGS

In the accompanying drawing forming a material part of this description, there is shown:

FIGS. 1 and 2 show how electron trapping affects the characteristics of traditional flash memory cells.

FIGS. 3-6 show a test structure and results of measurements of endurance characteristics of split gate memory cells with and without the nitridation treatment.

FIGS. 7-10 show the method of the invention, the resulting structure and how the nitridation treatment results in improved characteristics.

### DESCRIPTION OF THE PREFERRED EMBODIMENTS

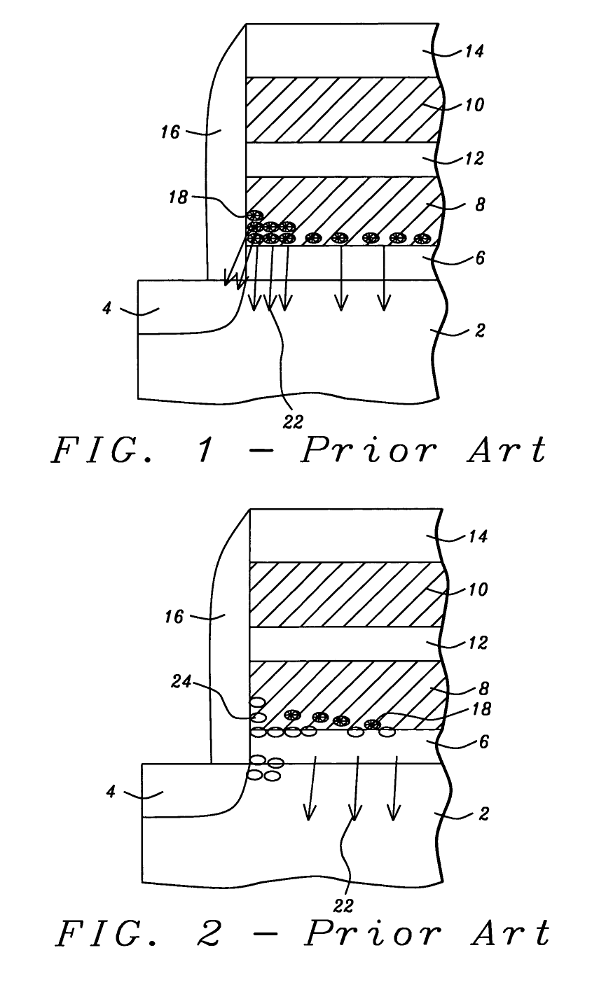

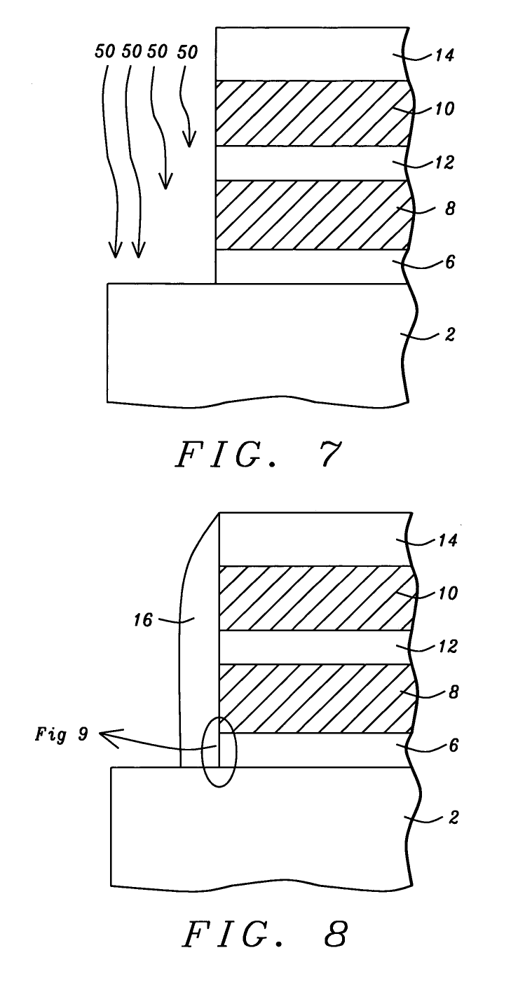

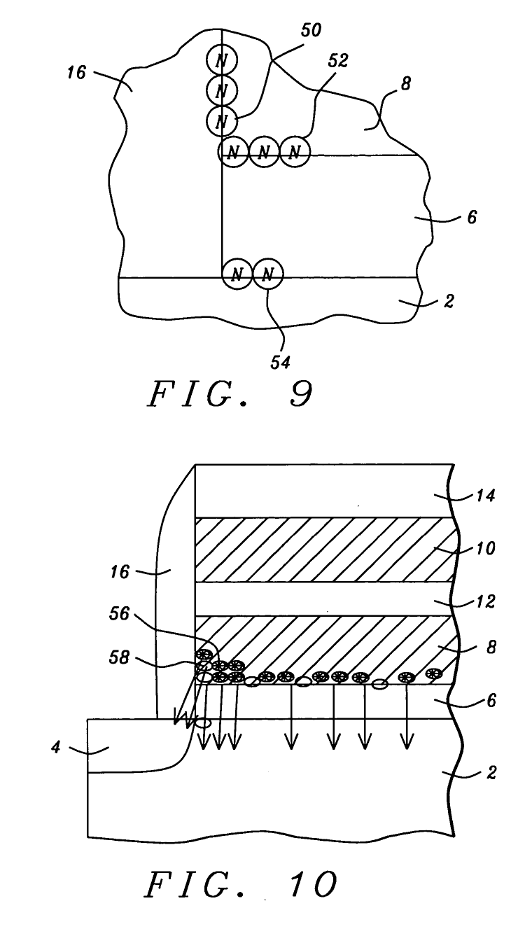

Preferred embodiments of the invention are well described with the aid of FIGS. 7-10. FIG. 7 shows the nitridation treatment, FIGS. 7 and 8 show the effect of the nitridation treatment on the structure and FIG. 10, to be compared with FIG. 2 for the case of no nitridation treatment, shows free and trapped electron distributions for the case of nitridation treatment. Referring now to FIG. 7, there is shown a portion of a flash memory cell, which could be a portion of a stacked-gate flash or of a split gate flash. Region 2 is a semiconductor region, which could be a silicon region, such as a silicon substrate. A gate insulator layer, 6, which could be a tunnel oxide layer, is formed over the semiconductor region. A floating gate, 8, that is often polysilicon, is disposed over the gate insulator layer and is separated from a control gate, 10, that is also often polysilicon, by an intergate insulator layer, 12, that can be an ONO layer. Top dielectric layer, 14, insulates the control gate. At this stage of the processing the floating gate sidewall, including its edge where it meets the gate insulator layer, is bare. A nitridation treatment is now performed. In preferred embodiments of the invention the nitridation could consist of a furnace anneal with NH₃ at a temperature of about 800 degrees Celsius for about 120 minutes or, alternatively, RTA NH₃ at a temperature of about 1000 degrees Celsius for about 10 seconds. The nitridation treatment is sufficiently moderate so as not to cause any new film growth nor cause enlargement of the gate insulator, effects that would result in a lowered erase efficiency. Introducing a nitridation treatment at this point is effective in not only incorporating nitrogen atoms at the floating gate sidewall surface, 50, but also nitrogen atoms diffuse along, and are incorporated at, the floating gate-gate insulator layer, 52, and floating gate-semiconductor interfaces, 54, predominately near the sidewall surface. A sidewall insulator spacer is now formed to obtain the structure of FIGS. 8 and 9, where, for clarity, the incorporated nitrogen atoms are shown in FIG. 9. Incorporated nitrogen atoms satisfy dangling bonds at the interfaces reducing electron traps there.

In a programming operation the control gate is biased positive with respect to the semiconductor region, 2, so that electrons are injected into the floating gate, 8, through the gate insulator layer. For a fresh flash memory cell the erase operation is again as shown in FIG. 1. The control gate is biased negative in the erase operation so that free electrons, 18, are injected into the drain region, 4, and semiconductor region, 2, by tunneling through the gate insulator layer, 6, and the sidewall insulator spacer, 16. However the tunneling at the floating gate edge, denoted by the arrows 20, dominates the tunneling current with relatively little contribution from the tunneling away from the edges, 22. This domination of the current by the tunneling at the floating gate edge will prevail for either drain side or channel erase schemes.

The effect of cycling for flash memory cells according to the invention is shown in FIG. 10, where for clarity the incorporated nitrogen atoms are not shown but it is understood that they are distributed as shown in FIG. 9. For the fresh memory cell the electron distribution, which is similar that for a fresh memory cell without nitridation treatment, is as shown in FIG. 1. In the erase operation the control gate is biased negative so that free electrons, 18, are injected into the drain region, 4, and semiconductor region, 2, by tunneling through the gate insulator layer, 6, and the sidewall insulator spacer, 16. Cycling here refers to repetition of the programming operation-erasing operation pair. The nitridation treatment significantly reduces the number of electron traps, but does not eliminate all of them. Therefore some electron trapping still occurs during the erase operation at the floating gate-gate insulator layer and floating gate-sidewall insulator spacer interfaces. There are many more free electrons, 56, near the floating gate edge and more electrons are trapped where there are more free electrons. However the number of trapping sites in the vicinity of the floating gate edge has been significantly reduced by the nitridation treatment. Thus, in the trapped electron distribution, 58, which results there are not many more electrons trapped near the floating gate edge, but the number is comparable to the moderate number trapped away from the edge. Since the number of trapped electrons near the floating gate edge is significantly smaller for flash memory cells with nitridation treatment than for those without nitridation treatment, there is a much smaller decrease in the tunneling current near the floating gate edge and thus there is a much smaller decrease in the erase efficiency.

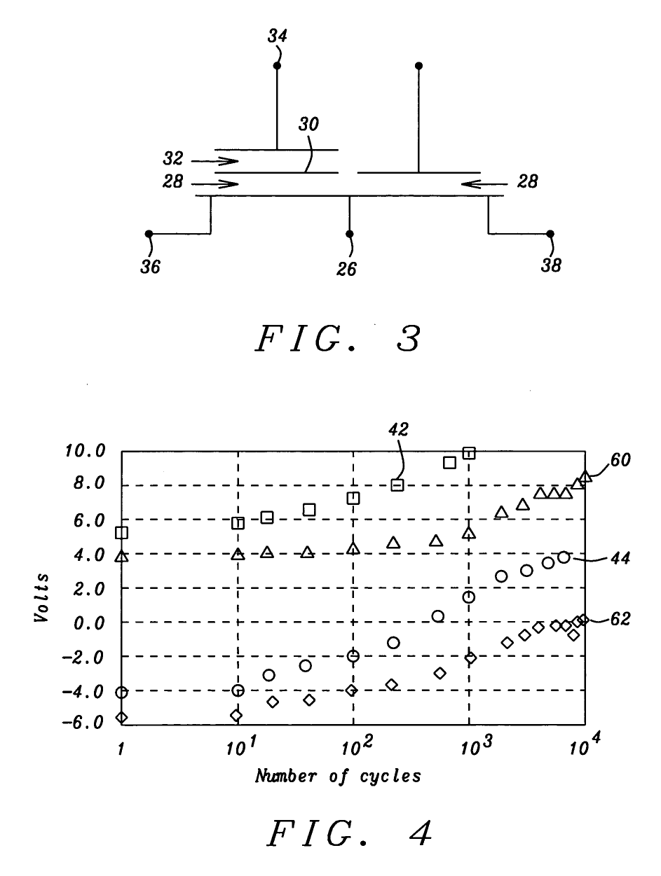

The trapped negative charge at the floating gate interfaces, being smaller for flash memory cells with nitridation treatment than for those without nitridation treatment, causes a smaller increase in the threshold voltage, Vₜ. Cycling therefore gives rise to smaller increases in Vₜ, corresponding to smaller numbers of trapped electrons at the floating gate-gate insulator and floating gate-sidewall insulator spacer interfaces. This reduced effect is shown quantitatively in FIGS. 4, 5 and 6 for a split gate memory cell test structure as shown in FIG. 3, where now the split gate flash memory cell has undergone a nitridation treatment. The gate region is composed of two stacks over a p-type silicon substrate, 26. The gate stack, on the drain, 36, side is composed of a tunnel oxide layer, 28, which is about 90 to 100 Angstroms thick; a polysilicon floating gate, 30, which is about 800 to 1000 Angstroms thick and whose width and length are each about 0.15 micrometers and a nitridation treatment has been performed over its exposed sidewalls according to the invention; an inter poly ONO layer, 32, with a thickness of about 60 Angstroms for each of the three layers and a polysilicon control gate, 34, which is about 1000 to 1500 Angstroms thick. The transfer stack on the source, 38, side is composed of the tunnel oxide layer, 28, over the substrate, 26, and a polysilicon transfer gate, 40, which is about 800 to 1000 Angstroms thick. In the cycling, the programming was accomplished by source side hot electron injection from the channel into the floating gate and the erase operation involved Fowler-Nordheim tunneling into the whole channel with the control gate biased negative and all other terminals grounded. In the read operation the threshold voltage, VT, is determined as the control gate voltage required to achieve 1 microampere of drain current.

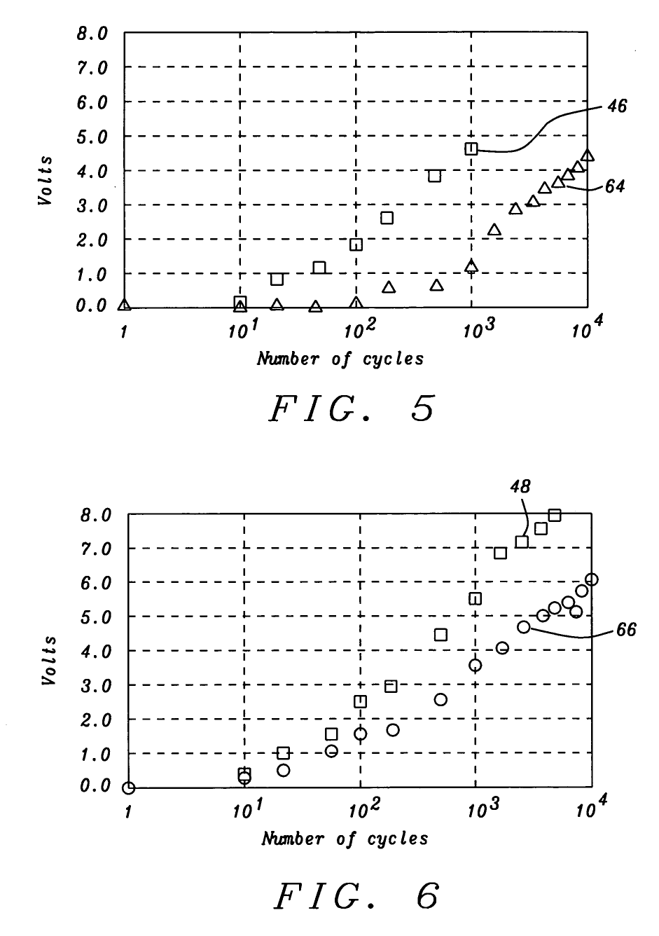

In FIG. 4, VT measured after programming, for a memory cell with nitridation treatment, is presented as curve 60 as a function of the number of cycles, N and VT measured after erasing, for a memory cell with nitridation treatment, is presented as curve 62 as a function of N. Accumulation of negative trapped charge is apparent by the monotonic increase of VT with N. The increases in VT that are obtained for the memory cell with nitridation treatment are shown directly in FIGS. 5 and 6, which present the VT shifts, VT minus the initial VT, after programming as curve 64 and after erasing as curve 66. It is clearly seen that the nitridation treatment gives rise to significant improvement. It takes about a factor of ten more cycles to produce a given after programming VT shift for a memory cell with nitridation treatment as for a memory cell without and it takes about a factor of ten more cycles to produce a given after erasing VT shift for a memory cell with nitridation treatment as for a memory cell without.

Although the effects of electron trapping have been discussed above with reference to flash memory cell structures the phenomena occurs in wider class of gate structures. Effects of trapped electrons, such as VT shifts, that are caused by electron trapping are undesirable for general gate structures. Electron trapping in traditional gate structures will generally predominately occur near gate edges. Thus, a nitridation treatment according to the preferred embodiments of the invention, which eliminates electron trapping sites especially near gate edges, will alleviate these affects. A nitridation treatment is performed at the stage of the process when the layers of a gate stack are formed except for sidewall insulator layers. At this stage of the processing the gate sidewall, including its edge where it meets the gate insulator layer, is bare. In preferred embodiments of the invention the nitridation could consist of a furnace anneal with NH₃ at a temperature of about 800 degrees Celsius for about 120 minutes or, alternatively, RTA NH₃ at a temperature of about 1000 degrees Celsius for about 10 seconds. The nitridation treatment is sufficiently moderate so as not to cause any new film growth nor cause enlargement of the gate insulator, effects that would result in a lowered erase efficiency. Introducing a nitridation treatment at this point is effective in not only incorporating nitrogen atoms at the gate sidewall surface, but also nitrogen atoms diffuse along, and are incorporated at, the gate-gate insulator layer and floating gate-semiconductor interfaces, predominately near the sidewall surface. A sidewall insulator spacer is then formed, after the nitridation treatment.

While the invention has been particularly shown and described with reference to the preferred embodiments thereof, it will be understood by those skilled in the art that various changes in form and detail may be made without departing from the spirit and scope of the invention.

1. A gate structure with improved endurance characteristics, comprising:
a semiconductor region within a substrate;
source and drain regions contained within said semiconductor region;
at least a gate stack, disposed over said semiconductor region, situated between said source and drain regions and containing a gate insulator layer formed over said semiconductor region, a conductive gate layer disposed over said gate insulator layer, with nitrogen atoms incorporated along the conductive gate layer sidewall.

2. The structure of claim 1 wherein a top gate stack layer is disposed over said conductive gate layer and a sidewall insulator layer, which could be an oxide layer, a nitride layer or a composite layer composed of layers of oxide and nitride, is disposed over sidewalls of said gate stack.

3. The structure of claim 1 wherein said semiconductor region is a silicon region.

4. The structure of claim 1 wherein said substrate is a silicon substrate.

5. The structure of claim 1 wherein said gate insulator layer is an oxide layer.

6. The structure of claim 1 wherein said conductive gate layer is a polysilicon layer.

7. The structure of claim 1 wherein said conductive gate layer is a gate of a semiconductor integrated circuit device.

8. The structure of claim 1 wherein said top gate stack layer is an insulator layer.

9. The structure of claim 1 wherein said nitrogen atoms extend to the conductive gate layer-gate insulator layer interface in the vicinity of the conductive gate layer edge.

10. A gate structure for flash memory cells with improved endurance characteristics, comprising:
a semiconductor region within a substrate;
source and drain regions contained within said semiconductor region;
at least a gate stack, disposed over said semiconductor region, situated between said source and drain regions and containing a gate insulator layer formed over said semiconductor region, a conductive floating gate layer over said gate insulator layer, an interpoly insulator layer disposed over said conductive gate layer, a conductive control gate layer and a top insulator layer and with a sidewall insulator layer disposed over sidewalls of said gate stack and with nitrogen atoms incorporated along the conductive gate layer sidewall-sidewall insulator layer interface and along the conductive gate layer-gate insulator layer interface in the vicinity of the conductive gate layer edge.

11. The structure of claim 10 wherein said semiconductor region is a silicon region.

12. The structure of claim 10 wherein said substrate is a silicon substrate.

13. The structure of claim 10 wherein said gate insulator layer is an oxide layer.

14. The structure of claim 10 wherein said conductive floating gate layer is a polysilicon layer.

15. The structure of claim 10 wherein said floating conductive gate layer is a floating gate of a stacked gate or of a split gate flash memory cell.

16. The structure of claim 10 wherein said interpoly insulator layer is an ONO layer.

17. The structure of claim 10 wherein said sidewall insulator layer is an oxide layer, a nitride layer or a composite layer composed of layers of oxide and nitride.

18. The structure of claim 10 wherein said conductive control gate layer is a polysilicon layer.

19. The structure of claim 10 wherein said top insulator layer is an oxide layer, a nitride layer or a composite layer composed of layers of oxide and nitride.

20. The structure of claim 10 wherein a transfer gate stack, comprising: said gate insulator layer; a conductive transfer gate layer, that could be a polysilicon layer, disposed over said gate insulator layer; a top transfer gate insulator layer, that could be an oxide layer or a nitride layer or a combination of these layers, disposed over said transfer gate layer and a transfer gate sidewall insulator layer, that could be an oxide layer or a nitride layer or a combination of these layers; is situated between said gate stack and said source region.

21. A method to fabricate a gate structure with improved endurance characteristics, comprising:
Providing a semiconductor region within a substrate;
Forming source and drain regions contained within said semiconductor region;
Forming at least a gate stack, disposed over said semiconductor region, situated between said source and drain regions and containing a gate insulator layer formed over said semiconductor region, a conductive gate layer disposed over said gate insulator layer and providing a nitrogen-based treatment on the sidewall of said conductive gate layer.

22. The method of claim 21 wherein said semiconductor region is a silicon region.

23. The method of claim 21 wherein said substrate is a silicon substrate.

24. The method of claim 21 wherein said gate insulator layer is an oxide layer.

25. The method of claim 21 wherein said conductive gate layer is a polysilicon layer.

26. The method of claim 21 wherein said conductive gate layer is a gate of a semiconductor integrated circuit device.

27. The method of claim 21 wherein a top gate stack layer, which could be an insulator layer, is formed over said conductive gate layer.

28. The method of claim 21 wherein a sidewall insulator layer, which could be an oxide layer, a nitride layer or a composite layer composed of layers of oxide and nitride, is formed over sidewalls of said gate stack.

29. The method of claim 21 wherein said nitrogen-based treatment is either a furnace anneal with NH₃ at a temperature of about 800 degrees Celsius for about 120 minutes or a RTA with NH₃ at a temperature of about 1000 degrees Celsius for about 10 seconds.

30. A method to fabricate a gate structure for flash memory cells with improved endurance characteristics, comprising:
forming a semiconductor region within a substrate;
forming source and drain regions contained within said semiconductor region;
forming at least a gate stack, disposed over said semiconductor region, situated between said source and drain regions and containing a gate insulator layer formed over said semiconductor region, a conductive floating gate layer disposed over said gate insulator layer, an interpoly insulator layer disposed over said conductive gate layer, a conductive control gate layer and a top insulator layer and with a sidewall insulator layer disposed over sidewalls of said gate stack and with a nitrogen treatment performed before forming said sidewall insulator.

31. The method of claim 30 wherein said semiconductor region is a silicon region.

32. The method of claim 30 wherein said substrate is a silicon substrate.

33. The method of claim 30 wherein said gate insulator layer is an oxide layer.

34. The method of claim 30 wherein said conductive floating gate layer is a polysilicon layer.

35. The method of claim 30 wherein said conductive floating gate layer is a floating gate of a split gate or of a stacked gate flash memory cell.

36. The method of claim 30 wherein said interpoly insulator layer is an ONO layer.

37. The method of claim 30 wherein said sidewall insulator layer is an oxide layer, a nitride layer or a composite layer composed of layers of oxide and nitride.

38. The method of claim 30 wherein said nitrogen treatment is either a furnace anneal with NH₃ at a temperature of about 800 degrees Celsius for about 120 minutes or a RTA with NH₃ at a temperature of about 1000 degrees Celsius for about 10 seconds.

39. The method of claim 30 wherein said conductive control gate layer is a polysilicon layer.

40. The method of claim 30 wherein said top insulator layer is an oxide layer, a nitride layer or a composite layer composed of layers of oxide and nitride.

41. The method of claim 30 wherein a transfer gate stack, comprising: said gate insulator layer; a conductive transfer gate layer, that could be a polysilicon layer, disposed over said gate insulator layer; a top transfer gate insulator layer, that could be an oxide layer or a nitride layer or a combination of these layers, disposed over said transfer gate layer and a transfer gate sidewall insulator layer, that could be an oxide layer or a nitride layer or a combination of these layers; is situated between said gate stack and said source region.
